(19) United States
(12) Patent Application Publication
(10) Pub. No.: US 2015/0090482 A1
(43) Pub. Date: Apr. 2, 2015

(54) CURABLE COMPOSITION FOR PRINTED CIRCUIT BOARD, CURED COATING FILM USING THE SAME, AND PRINTED CIRCUIT BOARD

(71) Applicant: TAIYO INK MFG. CO., LTD., Hiki-gun (JP)

(72) Inventors: Masayuki SHIMURA, Namegawa-machi (JP); Yoshiyuki FURUTA, Ranzan-machi (JP); Masao YUMOTO, Yorii-machi (JP)

(73) Assignee: TAIYO INK MFG. CO., LTD., Hiki-gun (JP)

(21) Appl. No.: 14/501,630

(22) Filed: Sep. 30, 2014

(30) Foreign Application Priority Data
Sep. 30, 2013 (JP) 2013-205344

(51) Int. Cl. C09D 11/101; H05K 1/03; C09D 133/14

(52) U.S. Cl. CPC C09D 11/101; C09D 133/14; H05K 1/0306; H05K 2201/2063
USPC 174/258; 522/167; 524/850; 174/250

(57) ABSTRACT

Provided are: a curable composition which can attain both good adhesion to a printed circuit board, particularly to a flexible substrate or the like; a resist coating film of the curable composition; and a printed circuit board comprising a resist pattern formed by the curable composition.

By the present invention, a curable composition for a printed circuit board comprising (A) a compound having a triazine ring, (B) a (meth)acrylate compound having a hydroxyl group and (C) a photopolymerization initiator; a coating film obtained by photo-curing the curable composition; and a printed circuit board comprising a resist pattern formed by the curable composition, are obtained.

### TECHNICAL FIELD

The present invention relates to a curable composition for a printed circuit board. More particularly, the present invention relates to a UV-curable composition to be used in an ink-jet method; a cured coating film for a printed circuit board using the same, which is used in at least one of resist formation, marking and etching; and a printed circuit board having a pattern obtained using the same.

### BACKGROUND ART

As methods for forming an etching resist, a solder resist, a symbol marking or the like on a printed circuit board, methods of curing an ink composed of a curable composition by irradiation with an active energy ray are known (Patent Documents 1 and 2). Further, in Patent Document 3, a solder resist composition comprising vinyltriazine is disclosed.

### RELATED ART DOCUMENTS

### Patent Documents

Patent Document 1: Japanese Unexamined Patent Application Publication No. 2013-135192

Patent Document 2: Japanese Unexamined Patent Application Publication No. S63-252498

Patent Document 3: Japanese Unexamined Patent Application Publication No. H8-335767

### SUMMARY OF THE INVENTION

### Problems to be Solved by the Invention

It is required that curable compositions for printed circuit boards, such as resist ink and marking ink to be formed on a printed circuit board, show adhesiveness to plastic substrates and conductor layers and have a high hardness, while maintaining various properties such as solder heat resistance. However, in such a curable composition as described above that is cured by irradiation with an active energy ray, particularly in a composition for a printed circuit board suitable for a method of curing an ink immediately after printing thereof, it is difficult to attain both favorable adhesion to a plastic substrate and conductor layer and high hardness.

The present invention was made to solve the above-described problems of conventional technologies and a main object of the present invention is to provide a curable composition for a printed circuit board, which shows both satisfactory adhesion to a plastic substrate and conductor layer and high hardness while maintaining various properties such as solder heat resistance.

Another object of the present invention is to provide a printed circuit board comprising a pattern-cured coating film which is formed using the curable composition for a printed circuit board and shows both satisfactory adhesiveness to a plastic substrate and conductor layer and high hardness while maintaining various properties such as solder heat resistance.

### Means for Solving the Problems

It was discovered that the above-described objects of the present invention can be achieved by a curable composition for a printed circuit board, which is characterized by comprising: a compound having a triazine ring; a (meth)acrylate compound having a hydroxyl group: and a photopolymerization initiator.

That is, the curable composition for a printed circuit board according to the present invention comprises: (A) a compound having a triazine ring; (B) a (meth)acrylate having a hydroxyl group; and (C) a photopolymerization initiator.

In the curable composition for a printed circuit board according to the present invention, it is preferred that the above-described (A) compound having a triazine ring contains at least one amino group.

In the curable composition for a printed circuit board according to the present invention, it is preferred that the above-described (A) compound having a triazine ring contains at least one unsaturated double bond.

It is preferred that the curable composition for a printed circuit board according to the present invention further comprises a bifunctional (meth)acrylate compound (excluding those which have a hydroxyl group).

Further, in the curable composition for a printed circuit board according to the present invention, it is preferred that the above-described bifunctional (meth)acrylate compound has a viscosity of 5 to 50 mPa·s at 25° C.

Still further, it is preferred that the curable composition for a printed circuit board according to the present invention further comprises a thermosetting component.

Yet still further, it is preferred that the curable composition for a printed circuit board according to the present invention has a viscosity of 5 to 50 mPa·s at 50° C.

The cured coating film according to the present invention is obtained by irradiating the above-described curable composition for a printed circuit board with light.

The printed circuit board according to the present invention comprises a pattern-cured coating film obtained by printing the above-described curable composition for a printed circuit board on a substrate and then irradiating the thus printed curable composition with light.

The printed circuit board according to the present invention comprises a pattern-cured coating film obtained by printing the above-described curable composition for a printed circuit board on a substrate by an ink-jet printing method and then irradiating the thus printed curable composition with light.

In the printed circuit board according to the present invention, it is preferred that the above-described substrate be a plastic substrate.

### Effects of the Invention

By the present invention, a curable composition for a printed circuit board which shows both satisfactory adhesion to a plastic substrate and conductor layer and high hardness while maintaining various properties such as solder heat resistance can be provided. In addition, a printed circuit board comprising a pattern-cured coating film which is formed using the curable composition for a printed circuit board and shows both satisfactory adhesion to a plastic substrate and conductor layer and high hardness while maintaining various properties such as solder heat resistance can be provided.

### MODE FOR CARRYING OUT THE INVENTION

The curable composition for a printed circuit board according to the present invention (hereinafter, also referred to as “curable composition”) comprises: (A) a compound having a triazine ring (component A); (B) a (meth)acrylate having a hydroxyl group (component B); and (C) a photopolymerization initiator (component C).

It is noted here that the term “(meth)acrylate” used herein is a general term for acrylates, methacrylates and mixtures thereof, and this is hereinafter applicable to all similar expressions.

### [(A) Compound Having a Triazine Ring]

As the (A) compound having a triazine ring, one which is known and commonly used can be employed. Specific examples thereof include guanamine, acetoguanamine, benzoguanamine and melamine. Such (A) compound having a triazine ring may be used individually, or two or more thereof may be used as a mixture. By incorporating a compound having a triazine ring, a coating film of the resulting curable resist composition for a printed circuit board is imparted with hardness, so that good pencil hardness as well as a balance between hardness and adhesiveness can be attained.

Thereamong, from the standpoint of improving the pencil hardness, a compound having a triazine ring which contains at least one of an amino group and an unsaturated double bond is preferred and a compound having a triazine ring which contains both an amino group and an unsaturated double bond is particularly preferred. Specific examples of such compound having a triazine ring include 2,4-diamino-6-vinyl-s-triazine (VT, manufactured by Shikoku Chemicals Corporation), 2,4-diamino-6-methacryloyloxyethyl-s-triazine (MAVT, manufactured by Shikoku Chemicals Corporation) and 2,4-diamino-6-vinyl-s-triazine isocyanuric acid adduct (VT-OK, manufactured by Shikoku Chemicals Corporation).

The amount of the (A) compound having a triazine ring to be incorporated is, in 100 parts by mass of the curable composition of the present invention, preferably 0.1 to 10 parts by mass, more preferably 0.5 to 5 parts by mass. The reason for this is because, when the amount is 0.1 parts by mass or more, sufficient effect of improving the adhesiveness is attained, while when the amount is 10 parts by mass or less, the (A) compound having a triazine ring is not likely to remain after photo-curing of the composition to cause deterioration in the properties of the cured product.

### [(B) (Meth)acrylate Compound Having a Hydroxyl Group]

As the (B) (meth)acrylate compound having a hydroxyl group, a low-molecular-weight material such as a monomer or oligomer can be used. Specifically, a material having a molecular weight in the range of 100 to 1,000, preferably 110 to 700, can be used.

Specific examples of the (B) (meth)acrylate compound having a hydroxyl group include 2-hydroxy-3-acryloyloxypropyl (meth)acrylate, 2-hydroxy-3-phenoxyethyl (meth)acrylate, 1,4-cyclohexane dimethanol mono(meth)acrylate, 2-hydroxyethyl(meth)acrylate, 2-hydroxypropyl (meth)acrylate, 4-hydroxybutyl (meth)acrylate, pentaerythritol tri(meth)acrylate, dipentaerythritol monohydroxypenta(meth)acrylate and 2-hydroxypropyl (meth)acrylate. Examples of commercial products thereof include ARONIX M-5700 (manufactured by Toagosei Co., Ltd.; trade name); 4HBA, 2HEA and CHDMMA (all of which are manufactured by Nippon Kasei Chemical Co., Ltd.; trade names); BHEA, HPA, HEMA and HPMA (all of which are manufactured by Nippon Shokubai Co., Ltd.; trade names); and LIGHT ESTER HO, LIGHT ESTER HOP and LIGHT ESTER HOA (all of which are manufactured by Kyoeisha Chemical Co., Ltd.; trade names). As the (B) (meth)acrylate compound having a hydroxyl group, these compounds/products may be used individually or a plurality thereof may be used in combination.

Thereamong, particularly, 2-hydroxy-3-acryloyloxypropyl acrylate, 2-hydroxy-3-phenoxyethylacrylate, 2-hydroxyethylacrylate, 2-hydroxypropyl acrylate, 4-hydroxybutyl acrylate and 1,4-cyclohexane dimethanol monoacrylate can be preferably used.

The amount of the (B) (meth)acrylate compound having a hydroxyl group to be incorporated is, in 100 parts by mass of the curable composition of the present invention, preferably 5 to 50 parts by mass, more preferably 10 to 30 parts by mass. When the amount of the (meth)acrylate having a hydroxyl group is 5 parts by mass or more, good adhesiveness, which is a characteristic feature of the composition of the present invention, is attained. Meanwhile, when the amount of the (meth)acrylate having a hydroxyl group is 50 parts by mass or less, a reduction in the ink compatibility can be inhibited.

Because of such combination of the component (A) and the component (B), the curable composition of the present invention can yield a cured coating film which shows excellent adhesion to both a plastic substrate and a conductor circuit metal and has high hardness. The curable composition of the present invention exhibits excellent substrate protection performance as, for example, a resist ink for a printed circuit board (such as an etching resist ink, a solder resist ink or a plating resist ink). In addition, the curable composition of the present invention also exhibits excellent properties as a cured coating film even with a small exposure does.

### [(C) Photopolymerization Initiator]

The (C) photopolymerization initiator is not particularly restricted and, for example, a photo-radical polymerization initiator can be employed. As this photo-radical polymerization initiator, any compound can be used as long as it generates a radical when irradiated with light, laser, electron beam or the like and initiates a radical polymerization reaction.

Examples of the (C) photopolymerization initiator include benzoins and benzoin alkyl ethers, such as benzoin, benzoin methyl ether, benzoin ethyl ether and benzoin isopropyl ether; alkylphenone-based photopolymerization initiators such as 2-hydroxy-2-methyl-1-phenyl-propane-1-one; acetophenones such as acetophenone, 2,2-dimethoxy-2-phenylacetophenone, 2,2-diethoxy-2-phenylacetophenone and 1,1-dichloroacetophenone; aminoacetophenones such as 2-methyl-1-[4-(methylthio)phenyl]-2-morpholinopropane-1-one, 2-benzyl-2-dimethylamino-1-(4-morpholinophenyl)-butane-1-one and N,N-dimethylaminoacetophenone; anthraquinones such as 2-methylanthraquinone, 2-ethylanthraquinone, 2-t-butyl anthraquinone and 1-chloroanthraquinone; thioxanthones such as 2,4-dimethylthioxanthone, 2,4-diethylthioxanthone, 2-chlorothioxanthone and 2,4-diisopropylthioxanthone; ketals such as acetophenone dimethyl ketal and benzyl dimethyl ketal; 2,4,5-triaryl imidazole dimer; riboflavin tetrabutyrate; thiol compounds such as 2-mercaptobenzimidazole, 2-mercaptobenzoxazole and 2-mercaptobenzothiazole; organic halogen compounds such as 2,4,6-tris-s-triazine, 2,2,2-tribromoethanol and tribromomethylphenyl sulfone; benzophenones and xanthones, such as benzophenone and 4,4′-bis-diethylaminobenzophenone; acylphosphine oxide-based photopolymerization initiators such as 2,4,6-trimethylbenzoyldiphenylphosphine oxide and bis(2,4,6-trimethylbenzoyl)-phenylphosphine oxide; and titanocenes such as bis(cyclopentadienyl)-di-phenyl-titanium, bis(cyclopentadienyl)-di-chloro-titanium, bis(cyclopentadienyl)-bis(2,3,4,5,6-pentafluorophenyl)titanium and bis(cyclopentadienyl)-bis(2,6-difluoro-3-(pyrrole-1-yl)phenyl)titanium.

These known and commonly used photopolymerization initiators may be used individually, or two or more thereof may be used as a mixture. Further, a photoinitiator aid, for example, tertiary amines such as ethyl-N,N-dimethylaminobenzoate, isoamyl-N,N-dimethylaminobenzoate, pentyl-4-dimethylaminobenzoate, triethylamine or triethanolamine, can also be added.

Examples of commercially available photopolymerization initiator include IRGACURE 261, 184, 369, 651, 500, 819, 907, 784 and 2959, DAROCUR 1116, 1173, CGI1700, CGI1750, CGI1850 and CG-24-61, and LUCIRIN TPO and CGI-784 (all of which are manufactured by BASF Japan Ltd.; trade names); DAICAT II (manufactured by Daicel Corporation; trade name); UVAC 1591 (manufactured by DAICEL-ALLNEX LTD.; trade name); RHODORSIL Photoinitiator 2074 (manufactured by Solvay; trade name); EBECRYL P36 (manufactured by DAICEL-ALLNEX LTD.; trade name); and ESACURE KIP150, KIP65LT, KIP100F, KT37, KT55, KT046, KIP75/B and ONE (all of which are manufactured by Fratelli Lamberti S.p.A; trade names).

The ratio of the (C) photopolymerization initiator to be incorporated is preferably in the range of 0.5 to 10 parts by mass with respect to 100 parts by mass of the curable composition of the present invention.

### (Bifunctional (Meth)acrylate Compound)

It is preferred that the curable composition for a printed circuit board according to the present invention further comprise a bifunctional (meth)acrylate compound (excluding those which have a hydroxyl group). By adding a bifunctional (meth)acrylate compound (excluding those which have a hydroxyl group), the compatibility of the components contained in the curable composition for a printed circuit board can be further improved.

Specific examples of the bifunctional (meth)acrylate compound (excluding those which have a hydroxyl group) include diol diacrylates such as 1,4-butanediol diacrylate, 1,6-hexanediol diacrylate, 1,9-nonanediol diacrylate and 1,10-decanediol diacrylate; glycol diacrylates, such as ethylene glycol diacrylate, diethylene glycol diacrylate, triethylene glycol diacrylate, tetraethylene glycol diacrylate, polyethylene glycol diacrylate, dipropylene glycol diacrylate, tripropylene glycol diacrylate, polypropylene glycol diacrylate, neopentyl glycol diacrylate, diol diacrylates obtained by adding at least one of ethylene oxide and propylene oxide to neopentyl glycol, and caprolactone-modified hydroxypivalic acid neopentyl glycol diacrylate; diacrylates having a cyclic structure, such as bisphenol A EO-adduct diacrylate, bisphenol A PO-adduct diacrylate, bisphenol A diglycidyl ether acrylic acid adduct, tricyclodecane dimethanol diacrylate, diol diacrylate obtained by adding at least one of ethylene oxide and propylene oxide to tris(2-hydroxyethyl)isocyanurate bisphenol A, hydrogenated dicyclopentadienyl diacrylate and cyclohexyl diacrylate; and diacrylates of isocyanuric acid, such as isocyanuric acid ethylene oxide-modified diacrylate.

Examples of commercially available bifunctional (meth)acrylate compound include LIGHT ACRYLATE 1,6HX-A, 1,9ND-A, 3EG-A and 4EG-A (manufactured by Kyoeisha Chemical Co., Ltd.; trade names); HDDA, 1,9-NDA, DPGDA and TPGDA (manufactured by DAICEL-ALLNEX LTD.; trade names); VISCOAT #195, #230, #230D, #260, #310HP, #335HP, #700HV and #540 (manufactured by Osaka Organic Chemical Industry Ltd.; trade names); and ARONIX M-208, M-211B, M-215, M-220, M-225, M-240 and M-270 ((manufactured by Toagosei Co., Ltd.; trade names).

Thereamong, from the standpoints of the viscosity and compatibility, diacrylates of diols containing an alkyl chain having 4 to 12 carbon atoms, particularly, 1,4-butanediol diacrylate, 1,6-hexanediol diacrylate, 1,9-nonanediol diacrylate and 1,10-decanediol diacrylate, are preferred.

The amount of such bifunctional acrylate compound to be incorporated is preferably 20 to 80 parts by mass, more preferably 40 to 70 parts by mass, in 100 parts by mass of the curable composition of the present invention. When the amount of the bifunctional (meth)acrylate is 20 parts by mass or more, the resulting ink has good compatibility. Meanwhile, when the amount is 80 parts by mass or less, the resulting ink has good adhesiveness.

The bifunctional (meth)acrylate compound has a viscosity of preferably 5 to 50 mPa·s, particularly preferably 5 to 30 mPa·s, at 25° C. In this viscosity range, the bifunctional (meth)acrylate compound shows good ease of handling as a diluent and the components can thus be homogeneously mixed. As a result, the entire surface of the resulting coating film can be expected to uniformly adhere to a substrate.

### (Thermosetting Component)

A thermosetting component may be added to the curable composition of the present invention. By adding a thermosetting component, the adhesiveness and heat resistance are expected to be improved. Examples of a thermosetting component that can be used in the present invention include amino resins such as melamine resins, benzoguanamine resins, melamine derivatives and benzoguanamine derivatives; block isocyanate compounds; cyclocarbonate compounds; thermosetting components having a cyclic (thio)ether group(s); bismaleimides; and known thermosetting resins such as carbodiimide resins. Block isocyanate compounds are particularly preferred because of their excellent storage stability.

The above-described thermosetting component having a plurality of cyclic (thio)ether groups in the molecule is a compound which contains a plurality of one or two of 3-, 4- and 5-membered cyclic (thio)ether groups in the molecule. Examples thereof include compounds having a plurality of epoxy groups in the molecule, namely polyfunctional epoxy compounds; compounds having a plurality of oxetanyl groups in the molecule, namely polyfunctional oxetane compounds; and compounds having a plurality of thioether groups in the molecule, namely episulfide resins.

Examples of the above-described polyfunctional epoxy compounds include, but not limited to, epoxidized vegetable oils such as ADK CIZER O-130P, ADK CIZER O-180A, ADK CIZER D-32 and ADK CIZER D-55, which are manufactured by ADEKA Corporation; bisphenol A-type epoxy resins such as jER828, jER834, jER1001 and jER1004, which are manufactured by Mitsubishi Chemical Corporation, EHPE3150 manufactured by Daicel Corporation, EPICLON 840, EPICLON 850, EPICLON 1050 and EPICLON 2055, which are manufactured by DIC Corporation, EPOTOHTO YD-011, YD-013, YD-127 and YD-128, which are manufactured by NIPPON STEEL & SUMIKIN CHEMICAL CO., LTD., D.E.R. 317, D.E.R. 331, D.E.R. 661 and D.E.R. 664, which are manufactured by The Dow Chemical Company, SUMI-EPDXY ESA-011, ESA-014, ELA-115 and ELA-128, which are manufactured by Sumitomo Chemical Co., Ltd., and A.E.R. 330, A.E.R. 331, A.E.R. 661 and A.E.R. 664, which are manufactured by Asahi kasei Corporation (all of the above are trade names); hydroquinone-type epoxy resin YDC-1312, bisphenol-type epoxy resin YSLV-80XY and thioether-type epoxy resin YSLV-120TE (all of which are manufactured by NIPPON STEEL & SUMIKIN CHEMICAL CO., LTD.); brominated epoxy resins such as jERYL 903 manufactured by Mitsubishi Chemical Corporation, EPICLON 152 and EPICLON 165, which are manufactured by DIC Corporation, EPOTOHTO YDB-400 and YDB-500, which are manufactured by NIPPON STEEL & SUMIKIN CHEMICAL CO., LTD., D.E.R. 542 manufactured by The Dow Chemical Company, SUMI-EPDXY ESB-400 and ESB-700, which are manufactured by Sumitomo Chemical Co., Ltd., and A.E.R. 711 and A.E.R. 714, which are manufactured by Asahi kasei Corporation (all of the above are trade names); novolac-type epoxy resins such as jER152 and jER154, which are manufactured by Mitsubishi Chemical Corporation, D.E.N. 431 and D.E.N. 438, which are manufactured by The Dow Chemical Company, EPICLON N-730, EPICLON N-770 and EPICLON N-865, which are manufactured by DIC Corporation, EPOTOHTO YDCN-701 and YDCN-704, which are manufactured by NIPPON STEEL & SUMIKIN CHEMICAL CO., LTD., EPPN-201, EOCN-1025, EOCN-1020, EOCN-104S and RE-306, which are manufactured by Nippon Kayaku Co., Ltd., SUMI-EPDXY ESCN-195X and ESCN-220, which are manufactured by Sumitomo Chemical Co., Ltd., and A.E.R. ECN-235 and ECN-299, which are manufactured by Asahi kasei Corporation, (all of the above are trade names); biphenol novolac-type epoxy resins such as NC-3000 and NC-3100, which are manufactured by Nippon Kayaku Co., Ltd.; bisphenol F-type epoxy resins such as EPICLON 830 manufactured by DIC Corporation, jER807 manufactured by Mitsubishi Chemical Corporation, and EPOTOHTO YDF-170, YDF-175 and YDF-2004, which are manufactured by NIPPON STEEL & SUMIKIN CHEMICAL CO., LTD. (all of the above are trade names); hydrogenated bisphenol A-type epoxy resins such as EPOTOHTO ST-2004, ST-2007 and ST-3000 (trade names), which are manufactured by NIPPON STEEL & SUMIKIN CHEMICAL CO., LTD.; glycidyl amine-type epoxy resins such as jER604 manufactured by Mitsubishi Chemical Corporation, EPOTOHTO YH-434 manufactured by NIPPON STEEL & SUMIKIN CHEMICAL CO., LTD., Ltd., and SUMI-EPDXY ELM-120 manufactured by Sumitomo Chemical Co., Ltd. (all of the above are trade names); hydantoin-type epoxy resins; alicyclic epoxy resins such as CELLOXIDE 2021 (trade name) manufactured by Daicel Corporation; trihydroxyphenyl methane-type epoxy resins such as YL-933 manufactured by Mitsubishi Chemical Corporation, and T.E.N., EPPN-501 and EPPN-502, which are manufactured by The Dow Chemical Company (all of the above are trade names); bixylenol-type or biphenol-type epoxy resins and mixtures thereof, such as YL-6056, YX-4000 and YL-6121 (all of which are trade names) manufactured by Mitsubishi Chemical Corporation; bisphenol S-type epoxy resins such as EBPS-200 manufactured by Nippon Kayaku Co., Ltd., EPX-30 manufactured by ADEKA Corporation and EXA-1514 (trade name) manufactured by DIC Corporation; bisphenol A novolac-type epoxy resins such as jER157S (trade name) manufactured by Mitsubishi Chemical Corporation; tetraphenylolethane-type epoxy resins such as jERYL-931 (trade name) manufactured by Mitsubishi Chemical Corporation; heterocyclic epoxy resins such as TEPIC (trade name) manufactured by Nissan Chemical Industries, Ltd.; diglycidyl phthalate resins such as BLEMMER DGT manufactured by NOF Corporation; tetraglycidyl xylenoylethane resins such as ZX-1063 manufactured by NIPPON STEEL & SUMIKIN CHEMICAL CO., LTD.; naphthalene group-containing epoxy resins such as ESN-190 and ESN-360, which are manufactured by NIPPON STEEL & SUMIKIN CHEMICAL CO., LTD., and HP-4032, EXA-4750 and EXA-4700, which are manufactured by DIC Corporation; epoxy resins having a dicyclopentadiene skeleton such as HP-7200 and HP-7200H manufactured by DIC Corporation; glycidyl methacrylate copolymer-based epoxy resins such as CP-50S and CP-50M manufactured by NOF Corporation; cyclohexylmaleimide-glycidyl methacrylate copolymer epoxy resins; epoxy-modified polybutadiene rubber derivatives (for example, PB-3600 manufactured by Daicel Corporation); and CTBN-modified epoxy resins (for example, YR-102 and YR-450 manufactured by NIPPON STEEL & SUMIKIN CHEMICAL CO., LTD.). These epoxy resins may be used individually, or two or more thereof may be used in combination. Thereamong, novolac-type epoxy resins, bixylenol-type epoxy resins, biphenol-type epoxy resins, biphenol novolac-type epoxy resins, naphthalene-type epoxy resins and mixtures thereof are particularly preferred.

Examples of the polyfunctional oxetane compounds include polyfunctional oxetanes such as bis[(3-methyl-3-oxcetanylmethoxy)methyl]ether, bis[(3-ethyl-3-oxcetanylmethoxy)methyl]ether, 1,4-bis[(3-methyl-3-oxcetanylmethoxy)methyl]benzene, 1,4-bis[(3-ethyl-3-oxcetanylmethoxy)methyl]benzene, (3-methyl-3-oxcetanyl)methyl acrylate, (3-ethyl-3-oxcetanyl)methyl acrylate, (3-methyl-3-oxcetanyl)methyl methacrylate, (3-ethyl-3-oxcetanyl)methyl methacrylate, and oligomers and copolymers thereof; and etherification products of an oxetane alcohol and a resin having a hydroxyl group such as a novolac resin, poly(p-hydroxystyrene), cardo-type bisphenol, calixarene, calix resorcin arene or a silsesquioxane. Other examples include copolymers of an unsaturated monomer having an oxetane ring and an alkyl (meth)acrylate.

Examples of the compounds having a plurality of cyclic thioether groups in the molecule include bisphenol A-type episulfide resin, YL7000 manufactured by Mitsubishi Chemical Corporation. Further, for example, an episulfide resin prepared by the same synthesis method, in which an oxygen atom of an epoxy group of a novolac-type epoxy resin is substituted with a sulfur atom, can also be used.

Examples of the amino resins such as melamine derivatives and benzoguanamine derivatives include methylol melamine compounds, methylol benzoguanamine compounds, methylol glycoluril compounds and methylol urea compounds. Further, alkoxymethylated melamine compounds, alkoxymethylated benzoguanamine compounds, alkoxymethylated glycoluril compounds and alkoxymethylated urea compounds can be obtained by converting the methylol group of the respective methylol melamine compounds, methylol benzoguanamine compounds, methylol glycoluril compounds and methylol urea compounds into an alkoxymethyl group. The type of this alkoxymethyl group is not particularly restricted and it may be, for example, a methoxymethyl group, an ethoxymethyl group, a propoxymethyl group or a butoxymethyl group. In particular, melamine derivatives whose formalin concentration is at a human- and environment-friendly level of 0.2% or less are preferred.

Examples of commercially available products of the above-described thermosetting components include CYMEL 300, 301, 303, 370, 325, 327, 701, 266, 267, 238, 1141, 272, 202, 1156, 1158, 1123, 1170, 1174, UFR65 and 300 (all of which are manufactured by Mitsui Cyanamid Co., Ltd.); and NIKALAC Mx-750, Mx-032, Mx-270, Mx-280, Mx-290, Mx-706, Mx-708, Mx-40, Mx-31, Ms-11, Mw-30, Mw-30HM, Mw-390, Mw-100LM and Mw-750LM (all of which are manufactured by Sanwa Chemical Co., Ltd.). These thermosetting components may be used individually, or two or more thereof may be used in combination.

An isocyanate compound and a block isocyanate compound are compounds having a plurality of isocyanate groups or blocked isocyanate groups in one molecule. Examples of such a compound having a plurality of isocyanate groups or blocked isocyanate groups in one molecule include polyisocyanate compounds and block isocyanate compounds. Here, the term “blocked isocyanate group” refers to an isocyanate group that is protected and thus temporarily inactivated by a reaction with a blocking agent. When heated to a prescribed temperature, the blocking agent dissociates to yield an isocyanate group. It has been confirmed that, by adding the above-described polyisocyanate compound or blocked isocyanate compound, the curability of the curable composition and the toughness of the cured product thereof are improved.

As such polyisocyanate compound, for example, an aromatic polyisocyanate, an aliphatic polyisocyanate or an alicyclic polyisocyanate may be employed.

Specific examples of the aromatic polyisocyanate include 4,4′-diphenylmethane diisocyanate, 2,4-tolylene diisocyanate, 2,6-tolylene diisocyanate, naphthalene-1,5-diisocyanate, o-xylylene diisocyanate, m-xylylene diisocyanate and 2,4-tolylene dimer.

Specific examples of the aliphatic polyisocyanate include tetramethylene diisocyanate, hexamethylene diisocyanate, methylene diisocyanate, trimethylhexamethylene diisocyanate, 4,4-methylenebis(cyclohexylisocyanate) and isophorone diisocyanate.

Specific examples of the alicyclic polyisocyanate include bicycloheptane triisocyanate as well as adducts, biurets and isocyanurates of the above-described isocyanate compounds.

As the blocked isocyanate compound, a product of an addition reaction between an isocyanate compound and an isocyanate blocking agent may be used. Examples of an isocyanate compound that can react with a blocking agent include the above-described polyisocyanate compounds.

Examples of the isocyanate blocking agent include phenolic blocking agents such as phenol, cresol, xylenol, chlorophenol and ethylphenol; lactam-based blocking agents such as ε-caprolactam, δ-valerolactam, γ-butyrolactam and β-propiolactam; activated methylene-based blocking agents such as ethyl acetoacetate and acetylacetone; alcohol-based blocking agents such as methanol, ethanol, propanol, butanol, amyl alcohol, ethylene glycol monomethyl ether, ethylene glycol monoethyl ether, ethylene glycol monobutyl ether, diethylene glycol monomethyl ether, propylene glycol monomethyl ether, benzyl ether, methyl glycolate, butyl glycolate, diacetone alcohol, methyl lactate and ethyl lactate; oxime-based blocking agents such as formaldehyde oxime, acetaldoxime, acetoxime, methylethyl ketoxime, diacetyl monooxime and cyclohexane oxime; mercaptan-based blocking agents such as butylmercaptan, hexylmercaptan, t-butylmercaptan, thiophenol, methylthiophenol and ethylthiophenol; acid amide-based blocking agents such as acetic acid amide and benzamide; imide-based blocking agents such as succinic acid imide and maleic acid imide; amine-based blocking agents such as xylidine, aniline, butylamine and dibutylamine; imidazole-based blocking agents such as imidazole and 2-ethylimidazole; and imine-based blocking agents such as methyleneimine and propyleneimine.

The blocked isocyanate compound may also be a commercially available one and examples thereof include SUMIDUR BL-3175, BL-4165, BL-1100 and BL-1265, DESMODUR TPLS-2957, TPLS-2062, TPLS-2078 and TPLS-2117 and DESMOTHERM 2170 and 2265 (all of which are manufactured by Sumika Bayer Urethane Co., Ltd.); CORONATE 2512, CORONATE 2513 and CORONATE 2520 (all of which are manufactured by Nippon Polyurethane Industry Co., Ltd.); B-830, B-815, B-846, B-870, B-874 and B-882 (all of which are manufactured by Mitsui Chemicals Inc.); and TPA-B80E, 17B-60PX and E402-B80T (all of which are manufactured by Asahi Kasei Chemicals Corporation). It is noted here that SUMIDUR BL-3175 and BL-4265 are produced using methylethyl oxime as a blocking agent. The above-described compounds having a plurality of isocyanate groups or blocked isocyanate groups in one molecule may be used individually, or two or more thereof may be used in combination.

The amount of such thermosetting component to be incorporated is preferably 1 to 30 parts by mass in 100 parts by mass of the curable composition of the present invention. When the amount of the thermosetting component is 1 part by mass or more, a coating film having sufficient toughness and heat resistance can be obtained. Meanwhile, when the amount is 30 parts by mass or less, a reduction in the storage stability can be inhibited.

In the curable composition for a printed circuit board according to the present invention, in addition to the above-described components, as required, known and commonly used additives, for example, a surface tension-adjusting agent; a surfactant; a matting agent; a polyester-based resin for adjusting the film physical properties; a polyurethane-based resin; a vinyl-based resin; an acrylic resin; a rubber-based resin; a wax; a known and commonly used coloring agent such as phthalocyanine blue, phthalocyanine green, iodine green, disazo yellow, crystal violet, titanium oxide, carbon black or naphthalene black; at least one of silicone-based, fluorine-based or polymer-based antifoaming agents and leveling agents; and adhesiveness-imparting agent such as an imidazole-based, thiazole-based or triazole-based adhesiveness-imparting agent or a silane-coupling agent, can be incorporated.

Further, in the curable composition for a printed circuit board according to the present invention, in addition to the above-described components, a resin may also be incorporated in such an amount that does not adversely affect the properties of the curable composition. As the resin, any resin that is known and commonly used can be employed; however, a (meth)acrylate compound having a polyene skeleton is preferred. The above-described polyene skeleton is preferably formed by polymerization of, for example, either or both of polybutadiene and isoprene. It is particularly preferred that the polyene skeleton be constituted by repeating units represented by the Formula (I):

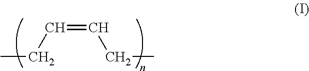

(wherein, n represents 10 to 300).

Because of the olefinic double bond of such repeating unit, the resulting curable resist composition for a printed circuit board is provided with flexibility as well as an increased conformability to a substrate, so that good adhesiveness is attained.

In the above-described polyene skeleton of the (meth)acrylate compound, the content of the repeating units represented by the Formula (I) is preferably not less than 50%, more preferably not less than 80%.

Further, the polyene skeleton of the (meth)acrylate compound may also contain a unit represented by the following Formula (II):

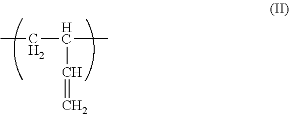

Specifically, for example, the following materials can be preferably used. That is, a liquid polybutadiene urethane (meth)acrylate obtained by urethane addition reaction of 2-hydroxyethyl (meth)acrylate with a hydroxyl group of a liquid polybutadiene via 2,4-tolylene diisocyanate; a liquid polybutadiene acrylate obtained by esterification reaction between a maleic anhydride-added maleated polybutadiene and 2-hydroxyacrylate; a liquid polybutadiene (meth)acrylate obtained by epoxy-esterification reaction between a carboxyl group of maleated polybutadiene and glycidyl (meth)acrylate; a liquid polybutadiene (meth)acrylate obtained by esterification reaction between an epoxidized polybutadiene, which is produced by allowing an epoxidizing agent to react with a liquid polybutadiene, and (meth)acrylic acid; a liquid polybutadiene (meth)acrylate obtained by dechlorination reaction of (meth)acrylic acid chloride with a hydroxyl group-containing liquid polybutadiene; and a liquid hydrogenated 1,2-polybutadiene (meth)acrylate obtained by modification of liquid hydrogenated 1,2-polybutadiene glycol, in which unsaturated double bond of a liquid polybutadiene having a hydroxyl group at both molecular terminals is hydrogenated, with urethane (meth)acrylate, can be preferably used.

Examples of commercial products thereof include NISSO PB TE-2000, NISSO PB TEA-1000, NISSO PB TE-3000 and NISSO PB TEAI-1000 (all of which are manufactured by Nippon Soda Co., Ltd.); CN301, CN303 and CN307 (all of which are manufactured by SARTOMER); BAC-15 (manufactured by Osaka Organic Chemical Industry Ltd.); BAC-45 (manufactured by Osaka Organic Chemical Industry Ltd.); and EY RESIN BR-45UAS (manufactured by Light Chemical Industries Co., Ltd.).

These (meth)acrylates having a polyene skeleton may be used individually or a plurality thereof may be used in combination.

Further, in the curable composition for a printed circuit board according to the present invention, a diluent may be incorporated for the purpose of adjusting the viscosity of the composition.

Examples of the diluent include dilution solvents, photoreactive diluents and heat-reactive diluents. Among these diluents, photoreactive diluents are preferred.

Examples of the photoreactive diluents include compounds having an unsaturated double bond, an oxetanyl group and/or an epoxy group, such as (meth)acrylates, vinyl ethers, ethylene derivatives, styrene, chloromethylstyrene, α-methylstyrene, maleic anhydride, dicyclopentadiene, N-vinylpyrrolidone, N-vinylformamide, xylylene dioxetane, oxetane alcohol, 3-ethyl-3-(phenoxymethyl)oxetane and resorcinol diglycidyl ether.

Thereamong, (meth)acrylates are preferred and monofunctional (meth)acrylates are more preferred. Examples of the monofunctional (meth)acrylates include (meth)acrylates such as methyl (meth)acrylate, ethyl (meth)acrylate, butyl (meth)acrylate, isobutyl (meth)acrylate, lauryl (meth)acrylate, stearyl (meth)acrylate, 2-hydroxyethyl (meth)acrylate, hydroxypropyl (meth)acrylate, hydroxybutyl (meth)acrylate and glycidyl methacrylate; and acryloyl morpholine.

The amount of such diluent to be incorporated is preferably 1 to 30 parts by mass in 100 parts by mass of the curable composition of the present invention.

Further, in the curable composition for a printed circuit board according to the present invention, a tri- or higher functional (meth)acrylate compound (excluding those which have a hydroxyl group) may be incorporated for the purpose of improving the tackiness of the composition after UV-curing.

Examples of the tri- or higher functional (meth)acrylate compound include polyfunctional acrylates represented by trimethylolpropane triacrylate, trimethylolmethane triacrylate, ethylene oxide-modified trimethylolpropane triacrylate, propylene oxide-modified trimethylolpropane triacrylate, epichlorohydrin-modified trimethylolpropane triacrylate, pentaerythritol tetraacrylate, tetramethylolmethane tetraacrylate, ethylene oxide-modified phosphoric acid triacrylate, propylene oxide-modified phosphoric acid triacrylate, epichlorohydrin-modified glycerol triacrylate, dipentaerythritol hexaacrylate, ditrimethylolpropane tetraacrylate and silsesquioxane modification products of these acrylates; methacrylate monomers corresponding to these acrylates; and ε-caprolactone-modified trisacryloxyethyl isocyanurate. The amount of such tri- or higher functional (meth)acrylate compound to be incorporated is preferably 1 to 40 parts by mass in 100 parts by mass of the curable composition of the present invention.

The curable composition for a printed circuit board according to the present invention which comprises the above-described components can be applied to printing methods such as screen printing method, ink-jet method, dip coating method, flow coating method, roll coating method, bar coater method and curtain coating method. Particularly, in cases where the curable composition for a printed circuit board according to the present invention is applied to an ink-jet method, the viscosity thereof at 50° C. is preferably 5 to 50 mPa·s, more preferably 5 to 20 mPa·s. By this, the curable composition can be printed smoothly without applying unnecessary load to an ink-jet printer.

In the present invention, the viscosity is measured at normal temperature (25° C.) or 50° C. in accordance with JIS K2283. As long as the viscosity is 150 mPa·s or less at normal temperature or 5 to 50 mPa·s at 50° C., the curable composition can be printed by an ink-jet printing method.

Further, in cases where the curable composition for a printed circuit board according to the present invention which has the above-described constitution is applied as an ink for ink-jet method, the composition can be printed on a flexible wiring board by a roll-to-roll process. In this case, by installing the below-described light source for light irradiation in the downstream of an ink-jet printer, a pattern-cured coating film can be formed quickly.

The light irradiation can be performed with ultraviolet radiation or an active energy ray; however, it is preferably performed with ultraviolet radiation. As the light source for this light irradiation, for example, a low-pressure mercury lamp, a medium-pressure mercury lamp, a high-pressure mercury lamp, an ultrahigh-pressure mercury lamp, a xenon lamp or a metal halide lamp is appropriate. In addition, electron beams, α-ray, β-ray, γ-ray, X-ray, neutron beams and the like can also be used.

Further, after the light irradiation, as required, the curable composition is cured by heating. Here, the heating temperature is, for example, 80 to 200° C. By performing the heating in such temperature range, the curable composition can be sufficiently cured. The heating time is, for example, 10 to 100 minutes.

Moreover, the curable composition for a printed circuit board according to the present invention can form a pattern-cured coating film which exhibits excellent adhesion to a printed circuit board that comprises a plastic substrate containing polyimide or the like as a main component and a conductor circuit arranged thereon, as well as excellent properties in terms of solder heat resistance, chemical resistance, solvent resistance, pencil hardness, resistance to electroless gold plating, bending resistance and the like.

### EXAMPLES

The present invention will now be described concretely by way of examples thereof; however, the present invention is not restricted to the following examples by any means. It is noted here that, unless otherwise specified, “part(s)” means “part(s) by mass” in the followings.

### Examples 1 to 7, Comparative Example 1 and 2

The components shown in Table 1 were blended at the respective ratios (unit:parts) shown in Table 1 and then pre-mixed using a stirrer to prepare a curable composition for a printed circuit board.

For the thus obtained curable composition and a coating film thereof, the following properties were evaluated.

1. Adhesion with Polyimide

The compositions obtained in Examples 1 to 7 and Comparative Example 1 and 2 were each coated on a polyimide substrate (UPILEX 25S) using a 30 μm applicator (manufactured by Erichsen GmbH & Co. KG) and then cured using a high-pressure mercury lamp (HMW-713, manufactured by ORC Manufacturing Co., Ltd.) at 150 mJ/cm². Thereafter, in a 150° C. hot air circulation-type drying oven, the cured composition was heat-treated for 60 minutes to obtain a cured coating film. The thus obtained sample was subjected to a cross-cut tape peeling test (JIS K5600).

o: No detachment was observed.

x: Detachment was observed.

The test results are shown in Table 2.

2. Adhesion with FR-4

The compositions obtained in Examples 1 to 7 and Comparative Example 1 and 2 were each coated on a FR-4 substrate using a 30 μm applicator (manufactured by Erichsen GmbH & Co. KG) and then cured using a high-pressure mercury lamp (HMW-713, manufactured by ORC Manufacturing Co., Ltd.) at 150 mJ/cm². Thereafter, in a 150° C. hot air circulation-type drying oven, the cured composition was heat-treated for 60 minutes. The thus obtained sample was subjected to a cross-cut tape peeling test (JIS K5600).

o: No detachment was observed.

x: Detachment was observed.

The test results are shown in Table 2.

3. Adhesion with Copper

The photocurable compositions for a printed circuit board that were obtained in Examples 1 to 7 and Comparative Example 1 and 2 were each coated on a copper foil (brand name is described below) using a 30 μm applicator (manufactured by Erichsen GmbH & Co. KG) and then cured using a high-pressure mercury lamp (HMW-713, manufactured by ORC Manufacturing Co., Ltd.) at 150 mJ/cm². Thereafter, in a 150° C. hot air circulation-type drying oven, the cured composition was heat-treated for 60 minutes. The thus obtained sample was subjected to a cross-cut tape peeling test.

o: No detachment was observed.

x: Detachment was observed.

The test results are shown in Table 2.

### 4. Pencil Hardness (Surface Hardness)

For the cured coating films obtained in the above 3., the pencil hardness of the surface was measured in accordance with JIS K5600-5-4.

### 5. Bending Resistance

A flexible copper-clad laminate constituted by a 25 μm-thick polyimide film and a comb-shaped copper wiring (wiring pattern) formed by 12 μm-thick copper foil was prepared (110 mm in length, 60 mm in width, copper wire width/space between copper wires=200 μm/200 μm). On this flexible copper-clad laminate substrate, the curable compositions were each coated to a film thickness of 15 μm by ink-jet printing using a piezo-type ink-jet printer. Here, immediately after the printing, the printed composition was pre-cured with UV using a high-pressure mercury lamp mounted on the ink-jet head. Then, the resultant was heat-cured at 150° C. for 1 hour to obtain a test piece. Using an MIT (Massachusetts Institute of Technology) tester, the thus cured test piece was repeatedly bent under the below-described conditions with its protection film facing inside, and the number of cycles at which electrical conduction was no longer observed was determined. For each evaluation, three test pieces were tested and the average number of cycles at which electrical conduction was no longer observed was calculated. The test conditions and evaluation criteria were as follows.

### MIT Resistance Test Conditions

Load: 500 gf

Angle: opposing angle of 135°

Rate: 175 times/minute

Tip: R0.38 mm cylinder

### Evaluation Criteria

o: 50 cycles or more

x: less than 50 cycles

### 6. Solvent Resistance

The cured coating films obtained in the above 3. were immersed in acetone for 30 minutes and the condition of each coating film was visually observed and evaluated based on the following criteria.

### Evaluation Criteria

o: Absolutely no change was observed.

x: Swelling or detachment of the coating film was observed.

### 7. Chemical Resistance

The cured coating films obtained in the above 3. were immersed in 5 wt % aqueous sulfuric acid solution for 10 minutes and the condition of each coating film was visually observed and evaluated based on the following criteria.

### Evaluation Criteria

o: Absolutely no change was observed.

x: Swelling or detachment of the coating film was observed.

### 8. Solder Heat Resistance

In accordance with the method of JIS C-5012, the cured coating films obtained in the above 3. were immersed in a 260° C. solder bath for 10 seconds and then subjected to a peeling test with a cellophane adhesive tape. Thereafter, the condition of each coating film was visually observed and evaluated based on the following criteria.

### Evaluation Criteria

o: The coating film showed no change.

x: The coating film was detached.

### 9. Resistance to Electroless Gold Plating

Using a commercially available electroless nickel plating bath and electroless gold plating bath, the cured coating films obtained in the above 3. were plated to a nickel thickness of 0.5 μm and a gold thickness of 0.03 μm. Then, the surface conditions of the resulting cured coating films were visually observed. The evaluation criteria were as follows.

### Evaluation Criteria

o: Absolutely no change was observed.

x: Prominent whitening or clouding was observed.

TABLE 1

| | Exam- | Exam- | Exam- | Exam- | Exam- | Exam- | Exam- | Comparative | Comparative |
|---|---|---|---|---|---|---|---|---|---|
| | ple 1 | ple 2 | ple 3 | ple 4 | ple 5 | ple 6 | ple 7 | Example 1 | Example 2 |
| Bifunctional acrylate monomer*¹ | 35 | 35 | 35 | 35 | 35 | 35 | 35 | 35 | 80 |
| Hydroxyl group-containing acrylate monomer*² | 45 | 45 | 45 | 45 | 45 | 45 | 45 | 45 | 0 |
| Trifunctional acrylate monomer*³ | 10 | 10 | 10 | 10 | 10 | 10 | 10 | 10 | 10 |
| Acid-containing methacrylate compound*⁴ | 3.75 | 3.75 | 3.75 | 3.75 | 2.5 | 2.5 | 3.75 | 3.75 | 3.75 |
| Initiator*⁵ | 1 | 1 | 1 | 1 | 1 | 1 | 1 | 1 | 1 |
| Initiator*⁶ | 2 | 2 | 2 | 2 | 2 | 2 | 2 | 2 | 2 |
| Initiator*⁷ | 2 | 2 | 2 | 2 | 2 | 2 | 2 | 2 | 2 |
| Thermosetting component*⁸ | 10 | 10 | 10 | 10 | 10 | 10 | 10 | 10 | 10 |
| Surface tension-adjusting agent*⁹ | 0.1 | 0.1 | 0.1 | 0.1 | 0.1 | 0.1 | 0.1 | 0.1 | 0.1 |
| Methacryl-containing triazine*¹⁰ | 0.5 | 1 | 3 | 5 | | | | | |
| Vinyltriazine derivative*¹¹ | | | | | 1 | | | | |
| Vinyltriazine*¹² | | | | | | 1 | | | |
| Triazine compound*¹³ | | | | | | | 1 | | |

The product names and abbreviations used in Table 1 are as follows.
*¹DPGDA; dipropylene glycol diacrylate (manufactured by BASF Japan Ltd.)
*²4HBA; 4-hydroxybutyl acrylate (manufactured by Nippon Kasei Chemical Co., Ltd.)
*³Laromer LR8863; EO-modified trimethylolpropane triacrylate (manufactured by BASF Japan Ltd.)
*⁴EBECRYL 168 (manufactured by Daicel-Allnex Ltd.)
*⁵DAROCUR 1173; 2-hydroxy-2-methyl-1-phenyl-propane-1-one (manufactured by BASF Japan Ltd.)
*⁶2-ethylAQ; 2-ethylanthraquinone (manufactured by BASF Japan Ltd.)
*⁷IRGACURE 819; bis(2,4,6-trimethylbenzoyl)-phenylphosphine oxide (manufactured by BASF Japan Ltd.)
*⁸BI7982; block isocyanate (manufactured by Baxenden Chemicals Ltd.)
*⁹BYK-307, silicon-based additive (manufactured by BYK)
*¹⁰MAVT; 2,4-diamino-6-methacryloyloxyethyl-s-triazine (manufactured by Shikoku Chemicals Corporation)
*¹¹VTOK; 2,4-diamino-6-vinyl-s-triazine isocyanuric acid adduct (manufactured by Shikoku Chemicals Corporation)
*¹²VT; 2,4-diamino-6-vinyl-s-triazine (manufactured by Shikoku Chemicals Corporation)
*¹³melamine

TABLE 2

| | Exam- | Exam- | Exam- | Exam- | Exam- | Exam- | Exam- | Comparative | Comparative |
|---|---|---|---|---|---|---|---|---|---|
| | ple 1 | ple 2 | ple 3 | ple 4 | ple 5 | ple 6 | ple 7 | Example 1 | Example 2 |
| Viscosity | ∘ | ∘ | ∘ | ∘ | ∘ | ∘ | ∘ | ∘ | ∘ |
| Adhesion with polyimide | ∘ | ∘ | ∘ | ∘ | ∘ | ∘ | ∘ | ∘ | x |
| Adhesion with FR-4 | ∘ | ∘ | ∘ | ∘ | ∘ | ∘ | ∘ | ∘ | x |
| Adhesion with copper | ∘ | ∘ | ∘ | ∘ | ∘ | ∘ | ∘ | ∘ | x |
| Pencil hardness | 5H | 5H | 6H | 7H | 5H | 5H | 4H | 2B | H |
| Bending resistance | ∘ | ∘ | ∘ | ∘ | ∘ | ∘ | ∘ | ∘ | x |
| Solvent resistance | ∘ | ∘ | ∘ | ∘ | ∘ | ∘ | ∘ | ∘ | x |
| Chemical resistance | ∘ | ∘ | ∘ | ∘ | ∘ | ∘ | ∘ | ∘ | x |
| Solder Heat Resistance | ∘ | ∘ | ∘ | ∘ | ∘ | ∘ | ∘ | x | x |
| Resistance to Electroless Gold | ∘ | ∘ | ∘ | ∘ | ∘ | ∘ | ∘ | x | x |
| Plating | | | | | | | | | |

As shown in Table 2, the curable compositions for a printed circuit board according to the present invention, which were obtained in Examples 1 to 7, showed good results for all of the adhesion with polyimide, adhesion with copper, pencil hardness on copper, bending resistance, solvent resistance, chemical resistance, solder heat resistance and resistance to electroless gold plating.

On the other hand, the composition of Comparative Example 1 which lacked the component A of the present invention did not have satisfactory performance, showing low pencil hardness and poor resistance to heat and electroless gold plating. In addition, the composition of Comparative Example 2 which lacked both of the components A and B showed poor results for all of the evaluated items.

The present invention is not restricted to the constitutions of the above-described embodiments and examples, and a variety of modifications can be made within the scope of the gist of the present invention.

### INDUSTRIAL APPLICABILITY

As described above, the curable composition for a printed circuit board according to the present invention shows excellent adhesion to both a plastic substrate and a conductor circuit metal and is capable of forming a fine pattern that is excellent in various properties such as solder heat resistance, solvent resistance, chemical resistance, pencil hardness and resistance to electroless gold plating.

Further, in order to make a composition sprayable by an ink-jet method, the composition is required to have a low viscosity. In general, low-viscosity photocurable compositions are considered to be poor in such properties as adhesiveness and heat resistance; however, the composition of the present invention can also be suitably used for forming a solder resist pattern on a printed circuit board by an ink-jet method even when the composition has a low viscosity. Therefore, the composition of the present invention can be applied not only to printed circuit board materials such as resist inks and marking inks, but also to applications such as UV-molded materials, materials for optical fabrication and 3D ink-jet materials.

1. A curable composition for a printed circuit board, comprising:
a compound having a triazine ring;
a (meth)acrylate having a hydroxyl group; and
a photopolymerization initiator.

2. The curable composition for a printed circuit board according to claim 1, wherein said compound having a triazine ring contains at least one amino group.

3. The curable composition for a printed circuit board according to claim 2, wherein said compound having a triazine ring contains at least one unsaturated double bond.

4. The curable composition for a printed circuit board according to claim 1, further comprising a bifunctional (meth)acrylate compound (which does not contain a hydroxyl) group.

5. The curable composition for a printed circuit board according to claim 4, wherein said bifunctional (meth)acrylate compound has a viscosity of 5 to 50 mPa·s at 25° C.

6. The curable composition for a printed circuit board according to claim 1, further comprising:
a thermosetting component.

7. The curable composition for a printed circuit board according to claim 1, having a viscosity of 5 to 50 mPa·s at 50° C.

8. A cured coating film, obtained by irradiating the curable composition for a printed circuit board according to claim 1 with light.

9. A printed circuit board, comprising:
a pattern-cured coating film obtained by printing the curable composition for a printed circuit board according to claim 1 on a substrate and then irradiating the thus printed curable composition with light.

10. A printed circuit board, comprising:
a pattern-cured coating film obtained by printing the curable composition for a printed circuit board according to claim 1 on a substrate by an ink-jet printing method and then irradiating the thus printed curable composition with light.

11. The printed circuit board according to claim 9, wherein said substrate is a plastic substrate.

12. The printed circuit board according to claim 10, wherein said substrate is a plastic substrate.

13. A cured coating film, obtained by irradiating the curable composition for a printed circuit board according to claim 2 with light.

14. A cured coating film, obtained by irradiating the curable composition for a printed circuit board according to claim 3 with light.

15. A cured coating film, obtained by irradiating the curable composition for a printed circuit board according to claim 4 with light.

16. A cured coating film, obtained by irradiating the curable composition for a printed circuit board according to claim 5 with light.

17. A printed circuit board, comprising:
a pattern-cured coating film obtained by printing the curable composition for a printed circuit board according to claim 2 on a substrate and then irradiating the thus printed curable composition with light.

18. A printed circuit board, comprising:
a pattern-cured coating film obtained by printing the curable composition for a printed circuit board according to claim 3 on a substrate and then irradiating the thus printed curable composition with light.

19. A printed circuit board, comprising:
a pattern-cured coating film obtained by printing the curable composition for a printed circuit board according to claim 4 on a substrate and then irradiating the thus printed curable composition with light.

20. A printed circuit board, comprising:
a pattern-cured coating film obtained by printing the curable composition for a printed circuit board according to claim 5 on a substrate and then irradiating the thus printed curable composition with light.
